(19) United States
(12) Patent Application Publication
(10) Pub. No.: US 2026/0148797 A1
(43) Pub. Date: May 28, 2026

(54) SEMICONDUCTOR MEMORY DEVICE

(71) Applicant: SK hynix Inc., Gyeonggi-do (KR)

(72) Inventors: Jun Hyun SONG, Gyeonggi-do (KR); Jee Yeon KEH, Gyeonggi-do (KR); Hong Ki MOON, Gyeonggi-do (KR); Yo Sep LEE, Gyeonggi-do (KR)

(21) Appl. No.: 19/403,236

(22) Filed: Nov. 28, 2025

(30) Foreign Application Priority Data
Nov. 28, 2024 (KR) 10-2024-0174064

(51) Int. Cl. G11C 29/00; G11C 17/18

(52) U.S. Cl. CPC G11C 29/787; G11C 17/18; G11C 29/76

(57) ABSTRACT

A fuse circuit of a semiconductor memory device includes: a plurality of fuse blocks. Each of the fuse blocks includes a first fuse set and a second fuse set, and is configured to output, in response to an access column address, a fuse hit signal indicating whether the access column address is programmed. The second fuse set is of a different type from the first fuse set.

### CROSS-REFERENCE TO RELATED APPLICATIONS

This patent document claims the priority and benefits of Korean patent application No. 10-2024-0174064, filed on Nov. 28, 2024, the disclosure of which is incorporated herein by reference in its entirety as part of the disclosure of this patent document.

### TECHNICAL FIELD

The technology and implementations disclosed in this patent document generally relate to a semiconductor memory device for storing data therein.

### BACKGROUND

A semiconductor memory device, such as a dynamic random access memory(DRAM), includes a plurality of memory cells each composed of a cell transistor and a cell capacitor. Defects may occur in the memory cells for various reasons (e.g., process limitations or the like). When such defects occur, the semiconductor memory device may fail to operate properly and thus be treated as a defective product.

As the integration density of semiconductor memory devices continues to increase, the likelihood of defects occurring in only a small number of memory cells becomes greater. Treating and discarding semiconductor memory devices that contain such a small number of defective cells as entirely defective products is an inefficient method of processing that lowers the yield of such semiconductor memory devices.

Accordingly, it is common practice to improve product yield by providing separate memory cells within the semiconductor memory device to replace defective cells. That is, to address malfunctioning of a chip caused by defects occurring in some memory cells, spare memory cells are pre-fabricated, and a repair operation can be used as necessary. In more detail, after testing, defective memory cells can be replaced with the spare memory cells through the repair operation.

### SUMMARY

Various embodiments of the present disclosure relate to a semiconductor memory device including one or more fuses required to perform the repair operation.

In accordance with an embodiment of the present disclosure, a fuse circuit of a semiconductor memory device may include a plurality of fuse blocks. Each of the fuse blocks may include a first fuse set and a second fuse set, and be configured to output, in response to an access column address, a fuse hit signal indicating whether the access column address is programmed. The second fuse set is of a different type from the first fuse set.

In accordance with another embodiment of the present disclosure, a fuse circuit of a semiconductor memory device may include a first fuse set configured to output a first original fuse hit signal indicating whether an access column address is programmed; a second fuse set configured to output a second original fuse hit signal indicating whether the access column address is programmed, the second fuse set being of a different type from the first fuse set; and a fuse router configured to route the first original fuse hit signal and the second original fuse hit signal and to output a first fuse hit signal and a second fuse hit signal.

In accordance with another embodiment of the present disclosure, a semiconductor memory device may include: a fuse circuit configured to output a fuse hit signal indicating whether an access column address is programmed, in response to the access column address; and a column decoder configured to generate a column address by converting the access column address based on the fuse hit signal, wherein the fuse circuit includes a first fuse set and a second fuse set which is of a different type from the first fuse set.

It is to be understood that both the foregoing general description and the following detailed description of the present disclosure are illustrative and explanatory and are intended to provide further explanation of the disclosure as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a block diagram illustrating a semiconductor memory device according to an embodiment of the present disclosure.

FIG. 2 is a block diagram illustrating the connection relationship among a normal memory cell array, a column decoder, and a fuse circuit shown in FIG. 1 according to an embodiment of the present disclosure.

FIG. 3 is a block diagram illustrating an example of a fuse block shown in FIG. 2 according to an embodiment of the present disclosure.

FIG. 4A is a block diagram illustrating an example of a fuse set shown in FIG. 3 according to an embodiment of the present disclosure.

FIG. 4B is a block diagram illustrating another example of the fuse set shown in FIG. 3 according to an embodiment of the present disclosure.

FIG. 4C is a block diagram illustrating another example of the fuse set shown in FIG. 3 according to an embodiment of the present disclosure.

FIG. 5 is a schematic diagram illustrating an example operation of a fuse power controller of a fuse block shown in FIG. 3 according to an embodiment of the present disclosure.

FIG. 6 is a schematic diagram illustrating an example operation of a fuse router of a fuse block shown in FIG. 3 according to an embodiment of the present disclosure.

FIG. 7 is a schematic diagram illustrating another example of the operation of a fuse router of a fuse block shown in FIG. 3 according to an embodiment of the present disclosure.

### DETAILED DESCRIPTION

The present disclosure provides implementations and examples of a semiconductor memory device for storing data therein that may be used in configurations to substantially address one or more technical or engineering issues and to mitigate limitations or disadvantages encountered in some other semiconductor memory devices. Some implementations of the present disclosure relate to a semiconductor memory device including one or more fuses required to perform the repair operation. In recognition of the issues above, the present disclosure may provide the semiconductor memory device including a fuse circuit having optimal reliability and optimal area efficiency. The present disclosure may provide a semiconductor memory device that can control different types of fuse sets (for example, fuse sets with different configurations and specifications) included in the fuse circuit according to various conditions, so that power consumption can be reduced and reliability characteristics can be improved.

Reference will now be made in detail to the embodiments of the present disclosure, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereinafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of effects capable of being directly or indirectly recognized through the present disclosure.

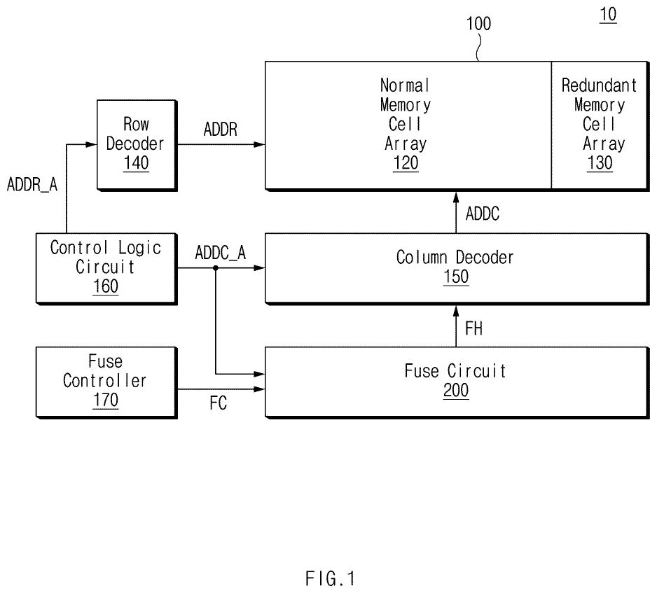

FIG. 1 is a block diagram illustrating a semiconductor memory device 10 according to an embodiment of the present disclosure.

Referring to FIG. 1, the semiconductor memory device 10 may be a volatile memory device capable of storing data. In the present disclosure, it is assumed that the semiconductor memory device 10 is a Dynamic Random Access Memory (DRAM) device, but the scope of the present disclosure is not limited thereto, and may encompass any of various types of memory devices that support high-speed operation.

A repair algorithm for repairing defective cells in the semiconductor memory device 10 may include a row repair method and a column repair method. In the row repair method, a row line containing a defective cell is repaired by replacing the defective cell with a redundancy row memory cell, whereas in the column repair method, a column line containing a defective cell is repaired by replacing the defective cell with a redundancy column memory cell. Here, the term “defective cell” may refer to a memory cell that is unable to perform normal operations among the memory cells that store and output data.

In the present disclosure, it is assumed for illustrative purposes that the semiconductor memory device 10 repairs defective cells using the column repair method; however, the technical concept disclosed herein may also be applied to a semiconductor memory device employing the row repair method.

The semiconductor memory device 10 may include a memory cell array 100, a row decoder 140, a column decoder 150, a control logic circuit 160, a fuse controller 170, and a fuse circuit 200.

The memory cell array 100 may include a normal memory cell array 120 and a redundant memory cell array 130.

Each of the normal memory cell array 120 and the redundant memory cell array 130 may have a structure in which multiple memory cells (e.g., DRAM cells) capable of storing data are arranged in a matrix including a plurality of rows and a plurality of columns.

The normal memory cell array 120 may include defective cells identified through testing. A column of the normal memory cell array 120 that includes defective cells may be repaired by being replaced with a column included in the redundant memory cell array 130.

The normal memory cell array 120 and the redundant memory cell array 130 may perform a specific operation (e.g., a read or write operation) by selecting a memory cell determined by a row address (ADDR) received from the row decoder 140 and a column address (ADDC) received from the column decoder 150.

The row decoder 140 may generate a row address (ADDR) by converting an access row address (ADDR_A) received from the control logic circuit 160, and may transmit the row address (ADDR) to the memory cell array 100. The access row address (ADDR_A) may refer to a row address of the normal memory cell array 120 to be accessed for the control logic circuit 160 to perform a specific operation (e.g., a read or write operation). In the present disclosure, the operation in which the row decoder 140 converts the access row address (ADDR_A) may be an operation of bypassing the access row address (ADDR_A).

The column decoder 150 may generate a column address (ADDC) by converting an access column address (ADDC_A) received from the control logic circuit 160, and may transmit the column address (ADDC) to the memory cell array 100. The access column address (ADDC_A) may refer to a column address of the normal memory cell array 120 to be accessed for the control logic circuit 160 to perform a specific operation (e.g., a read or write operation).

The column decoder 150 may convert an access column address (ADDC_A) based on a fuse hit signal (FH) received from (for example, activated by) the fuse circuit 200. When the fuse hit signal (FH) indicates that the access column address (ADDC_A) is not a fail address, the column decoder 150 may bypass the access column address (ADDC_A) and output the column address (ADDC). Here, the fail address may refer to an address of a column that corresponds to the access column address (ADDC_A) while simultaneously having a defective cell.

When the fuse hit signal (FH) indicates that the access column address (ADDC_A) is a fail address, the column decoder 150 may convert the access column address (ADDC_A) into an address (hereinafter referred to as a “repair address”) of a column included in the redundant memory cell array 130, and may output the repair address as the column address (ADDC).

The control logic circuit 160 may control the overall operation of the semiconductor memory device 10. The control logic circuit 160 may perform read or write operations on the memory cell array 100. For this purpose, the control logic circuit 160 may transmit the access row address (ADDR_A) to the row decoder 140, and may transmit the access column address (ADDC_A) to the column decoder 150 and the fuse circuit 200.

In addition, the control logic circuit 160 may communicate with an external memory controller (not shown) that controls the semiconductor memory device 10. The control logic circuit 160 may provide the fuse controller 170 with information necessary for generating a fuse control signal (FC).

The fuse controller 170 may transmit a fuse control signal (FC) to the fuse circuit 200 to control the operation of the fuse circuit 200. In some embodiments, the fuse control signal (FC) may include a fuse power control signal for controlling power consumption of the fuse circuit 200. In some embodiments, the fuse control signal (FC) may include a fuse mode control signal for determining the correspondence between the fuse circuit 200 and the normal memory cell array 120. In some embodiments, the fuse control signal (FC) may include a redundancy switching control signal for changing a repair address.

In some embodiments, unlike FIG. 1, the fuse controller 170 may also be implemented as a portion of the control logic circuit 160.

The fuse circuit 200 may include fuses in which the column addresses of defective cells detected through testing (e.g., wafer testing or package testing) performed at a specific stage (e.g., wafer or package level) during the manufacturing process of the semiconductor memory device 10 are programmed (for example, fuses in which the defective cell addresses are programmed). Examples of fuse programming methods may include an electrical fuse method in which the fuse is melted and blown by overcurrent, a laser-blowing method in which the fuse is burned and blown by a laser beam, and a laser-shorting method in which a junction is short-circuited by a laser beam. In addition, the addresses of defective cells may also be detected through testing to be performed after shipment of the semiconductor memory device 10, and the fuse circuit 200 may additionally store such defective cell addresses.

The fuse circuit 200 may generate a fuse hit signal (FH) based on whether the received access column address (ADDC_A) is programmed in the fuses of the fuse circuit 200, and may transmit the fuse hit signal (FH) to the column decoder 150.

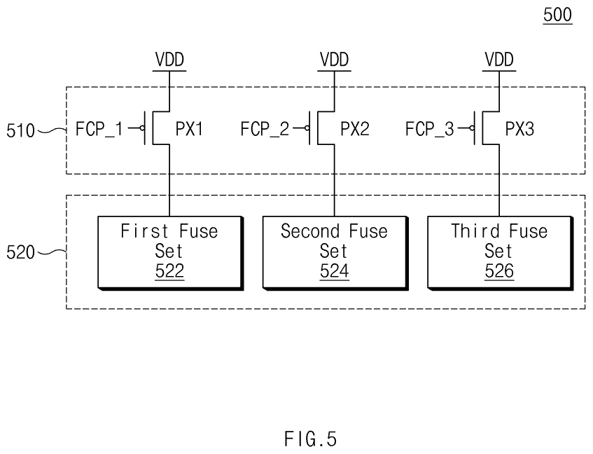

The fuse circuit 200 may operate according to a mode to be determined based on the fuse control signal (FC), and a detailed description thereof is provided herein below with reference to FIG. 5 and subsequent figures.

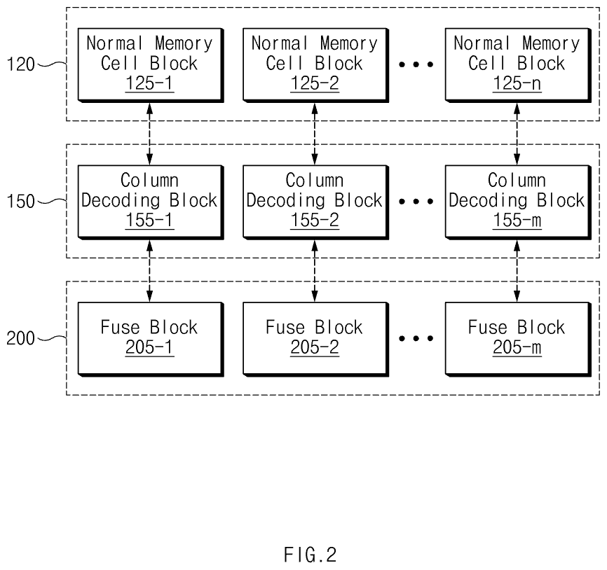

FIG. 2 is a block diagram illustrating the correspondence relationship among the normal memory cell array 120, the column decoder 150, and the fuse circuit 200 shown in FIG. 1.

Referring to FIG. 2, the normal memory cell array 120 may include first to n-th (where n is an integer of 2 or greater) normal memory cell blocks (125-1 to 125-n). That is, the normal memory cell array 120 may be divided into n sub-blocks. In some embodiments, n may be 16, but the scope of the present disclosure is not limited thereto.

The column decoder 150 may include first to m-th (where m is an integer of 2 or greater) column decoding blocks (155-1 to 155-m). That is, the column decoder 150 may be divided into m sub-blocks. In the example of FIG. 2, m and n are identical integers, and the first to m-th column decoding blocks (155-1 to 155-m) may correspond to the first to n-th normal memory cell blocks (125-1 to 125-n), respectively. In some embodiments, each of the first to m-th column decoding blocks (155-1 to 155-m) may convert an access column address (ADDC_A) corresponding to the associated normal memory cell block among the first to n-th normal memory cell blocks (125-1 to 125-n), thereby generating a column address (ADDC).

The fuse circuit 200 may include first to m-th fuse blocks (205-1 to 205-m). That is, the fuse circuit 200 may be divided into m sub-blocks. In the example of FIG. 2, the first to m-th fuse blocks (205-1 to 205-m) may correspond to the first to m-th column decoding blocks (155-1 to 155-m). In addition, the first to m-th fuse blocks (205-1 to 205-m) may correspond to the first to n-th normal memory cell blocks (125-1 to 125-n), respectively. In some embodiments, each of the first to m-th fuse blocks (205-1 to 205-m) may generate a fuse hit signal (FH) indicating whether an access column address (ADDC_A) corresponding to the associated normal memory cell block among the first to n-th normal memory cell blocks (125-1 to 125-n) is a fail address.

In FIG. 2, the first to m-th column decoding blocks (155-1 to 155-m) and the first to n-th normal memory cell blocks (125-1 to 125-n) are illustrated as being in a one-to-one correspondence, but the scope of the present disclosure is not limited thereto. In some embodiments, the first to m-th column decoding blocks (155-1 to 155-m) and the first to n-th normal memory cell blocks (125-1 to 125-n) may correspond to each other in a (1:k) ratio (where ‘k’ is an integer of 2 or greater). For example, when ‘k’ is 4, four normal memory cell blocks may correspond to one column decoding block. In this case, the first to m-th fuse blocks (205-1 to 205-m) and the first to n-th normal memory cell blocks (125-1 to 125-n) may also correspond to each other in a (1:k) ratio.

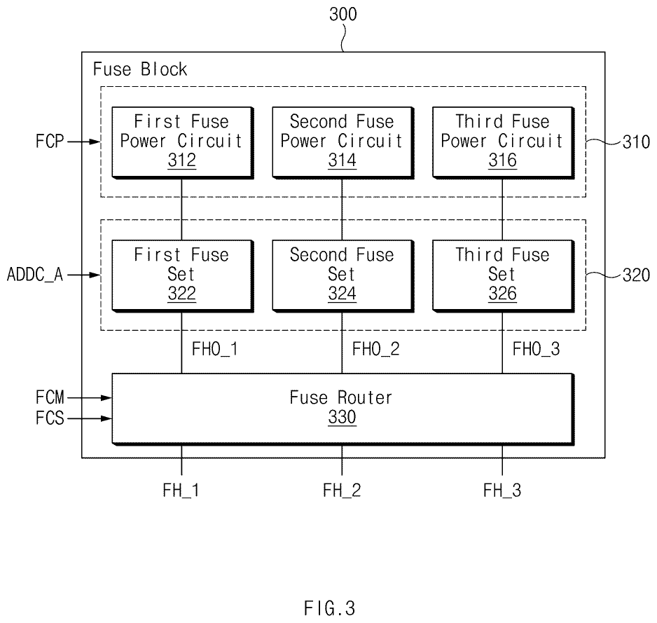

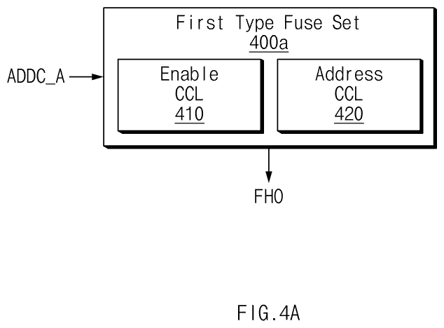

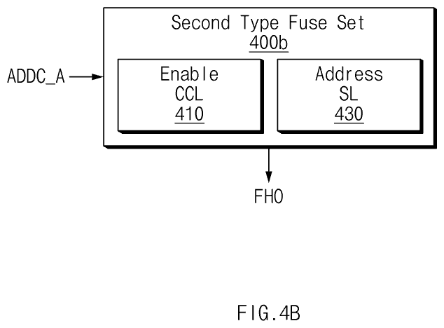

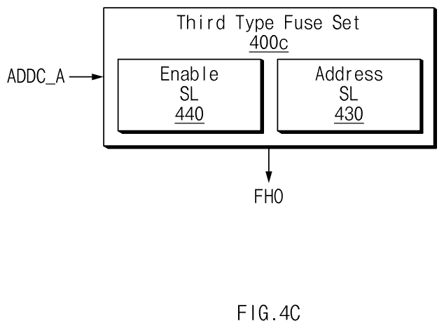

FIG. 3 is a block diagram illustrating an example of the fuse block shown in FIG. 2. FIG. 4A is a block diagram illustrating an example of one of the fuse sets shown in FIG. 3. FIG. 4B is a block diagram illustrating another example of one of the fuse sets shown in FIG. 3. FIG. 4C is a block diagram illustrating another example of the fuse set shown in FIG. 3.

Referring to FIG. 3, the fuse block 300 may correspond to one of the first to m-th fuse blocks (205-1 to 205-m). That is, each of the first to m-th fuse blocks (205-1 to 205-m) may have a structure and function corresponding to the fuse block 300.

The fuse block 300 may output fuse hit signals (FH_1 to FH_3) indicating whether the access column address (ADDC_A) is programmed in the fuse block 300 in response to (for example, an input of) the access column address (ADDC_A).

The fuse block 300 may include a fuse power controller 310, a fuse circuit 320, and a fuse router 330.

The fuse power controller 310 may control power to be supplied to the fuse circuit 320 according to a fuse power control signal (FCP) included in the fuse control signal (FC). The fuse power controller 310 may include first to third fuse power circuits (312 to 316).

The first to third fuse power circuits (312 to 316) may be electrically connected to the first to third fuse sets (322 to 326) of the fuse circuit 320, respectively. Each of the first to third fuse power circuits (312 to 316) may receive (for example, activate) a power-supply voltage (e.g., VDD) from the semiconductor memory device 10, and may selectively supply or not supply the power-supply voltage to the corresponding one of the first to third fuse sets (322 to 326) according to the fuse power control signal (FCP).

The fuse circuit 320 may include first to third fuse sets (322 to 326). Two or more of the first to third fuse sets (322 to 326) may be of different types (for example, configurations, specifications, such as described with respect to FIGS. 4A to 4C herein below). In other words, the fuse circuit 320 may have a structure in which fuse sets of two or more different types are mixed and arranged.

Each of the first to third fuse sets (322 to 326) may include an enable fuse latch (e.g., 410 and 440 in FIGS. 4A to 4C) in which data indicating whether the corresponding fuse set is being used for the access column address (ADDC_A) is programmed, and an address fuse latch (e.g., 420 and 430 in FIGS. 4A to 4C) in which a fail address of a defective cell included in the normal memory cell block corresponding to the fuse set is programmed.

Hereinafter, the types of fuse sets that can be included in the first to third fuse sets (322 to 326) will be described with reference to FIGS. 4A to 4C.

Referring to FIG. 4A, a first-type fuse set 400a may include an enable cross-coupled latch (CCL) 410 and an address cross-coupled latch (CCL) 420.

The enable CCL 410 may include a fuse in which data indicating whether the first-type fuse set 400a is being used for the access column address (ADDC_A) (or whether the access column address (ADDC_A) corresponds to the first-type fuse set 400a) is programmed. The address CCL 420 may include a fuse in which a fail address of a defective cell included in the normal memory cell block corresponding to the first-type fuse set 400a is programmed.

When the access column address (ADDC_A) is input to the first-type fuse set 400a, the enable CCL 410 may generate a result value indicating whether the first-type fuse set 400a is being used for the access column address (ADDC_A), and the address CCL 420 may generate a result value indicating whether the access column address (ADDC_A) is a fail address.

In one embodiment, the first-type fuse set 400a may compare the result value generated by the enable CCL 410 with the result value generated by the address CCL 420, and may generate an original fuse hit signal (FHO) based on the comparison result. For this purpose, the first-type fuse set 400a may include a comparison circuit (not shown) for comparing the two result values. The original fuse hit signal (FHO) may indicate whether the access column address (ADDC_A) is programmed in the first-type fuse set 400a.

If the access column address (ADDC_A) corresponds to the first-type fuse set 400a and is a fail address, the first-type fuse set 400a may generate an original fuse hit signal (FHO) at a logic high level. In contrast, if the access column address (ADDC_A) does not correspond to the first-type fuse set 400a or is not a fail address, the first-type fuse set 400a may generate the original fuse hit signal (FHO) at a logic low level.

Referring to FIG. 4B, a second-type fuse set 400b may include an enable cross-coupled latch (CCL) 410 and an address single latch (SL) 430.

The enable CCL 410 may include a fuse in which data indicating whether the second-type fuse set 400b is being used for the access column address (ADDC_A) (or whether the access column address (ADDC_A) corresponds to the second-type fuse set 400b) is programmed. The address SL 430 may include a fuse in which a fail address of a defective cell included in the normal memory cell block corresponding to the second-type fuse set 400b is programmed.

When the access column address (ADDC_A) is input to the second-type fuse set 400b, the enable CCL 410 may generate a result value indicating whether the second-type fuse set 400b is being used for the access column address (ADDC_A), and the address SL 430 may generate a result value indicating whether the access column address (ADDC_A) is a fail address.

In one embodiment, the second-type fuse set 400b may compare the result value generated by the enable CCL 410 with the result value generated by the address SL 430, and may generate an original fuse hit signal (FHO) based on the comparison result. For this purpose, the second-type fuse set 400b may include a comparison circuit (not shown) for comparing the two result values. The original fuse hit signal (FHO) may be a signal indicating whether the access column address (ADDC_A) is programmed in the second-type fuse set 400b.

If the access column address (ADDC_A) corresponds to the second-type fuse set 400b and is a fail address, the second-type fuse set 400b may generate an original fuse hit signal (FHO) at a logic high level. In contrast, if the access column address (ADDC_A) does not correspond to the second-type fuse set 400b or is not a fail address, the second-type fuse set 400b may generate the original fuse hit signal (FHO) at a logic low level.

Referring to FIG. 4C, a third-type fuse set 400c may include an enable single latch (SL) 440 and an address single latch (SL) 430.

The enable SL 440 may include a fuse in which data indicating whether the third-type fuse set 400c is being used for the access column address (ADDC_A) (or whether the access column address (ADDC_A) corresponds to the third-type fuse set 400c) is programmed. The address SL 430 may include a fuse in which a fail address of a defective cell included in the normal memory cell block corresponding to the third-type fuse set 400c is programmed.

When the access column address (ADDC_A) is input to the third-type fuse set 400c, the enable SL 440 may generate a result value indicating whether the third-type fuse set 400c is being used for the access column address (ADDC_A), and the address SL 430 may generate a result value indicating whether the access column address (ADDC_A) is a fail address.

In one embodiment, the third-type fuse set 400c may compare the result value generated by the enable SL 440 with the result value generated by the address SL 430, and may generate an original fuse hit signal (FHO) based on the comparison result. For this purpose, the third-type fuse set 400c may include a comparison circuit (not shown) for comparing the two result values. The original fuse hit signal (FHO) may be a signal indicating whether the access column address (ADDC_A) is programmed in the third-type fuse set 400c.

If the access column address (ADDC_A) corresponds to the third-type fuse set 400c and is a fail address, the third-type fuse set 400c may generate an original fuse hit signal (FHO) at a logic high level. In contrast, if the access column address (ADDC_A) does not correspond to the third-type fuse set 400c or is not a fail address, the third-type fuse set 400c may generate the original fuse hit signal (FHO) at a logic low level.

The enable CCL 410 and the address CCL 420 may refer to CCL-based fuse latch circuits. The enable SL 440 and the address SL 430 may refer to SL-based fuse latch circuits.

Referring again to FIG. 3, whereas the CCL-based fuse latch circuit exhibits excellent Neutron Soft Error Rate (NSER) characteristics, which serve as an indicator of reliability, the CCL-based fuse latch circuit occupies a relatively large area, thereby degrading area efficiency. In contrast, the SL-based fuse latch circuit occupies a relatively small area, so that the SL-based fuse latch circuit provides superior area efficiency, resulting in reduction in NSER characteristics.

In the present disclosure, the first to third fuse sets (322 to 326) may be implemented as two or more fuse sets selected from among the first to third types of fuse sets (400a to 400c). In other words, as the first to third fuse sets (322 to 326) are configured through a combination of CCL-based fuse latch circuits and SL-based fuse latch circuits, both NSER characteristics and area efficiency can be optimized.

For example, the first fuse set 322 may have the structure of the first-type fuse set 400a, and each of the second and third fuse sets (324, 326) may have the structure of the third-type fuse set 400c.

In another example, the first fuse set 322 may have the structure of the first-type fuse set 400a, the second fuse set 324 may have the structure of the second-type fuse set 400b, and the third fuse set 326 may have the structure of the third-type fuse set 400c.

Although two examples have been described above, the scope of the present disclosure is not limited thereto, and the first to third fuse sets (322 to 326) may be implemented in various combinations to include two or more different types.

In the following description of FIG. 5 and subsequent figures, it is assumed that, as in the first example above, the first fuse set 322 has the structure of the first-type fuse set 400a, and each of the second and third fuse sets (324, 326) has the structure of the third-type fuse set 400c.

The fuse router 330 may control electrical connections between the column decoder 150 and the first to third fuse sets (322 to 326). The fuse router 330 may receive first to third original fuse hit signals (FHO_1 to FHO_3) from the first to third fuse sets (322 to 326), and may output first to third fuse hit signals (FH_1 to FH_3) according to the established electrical connections.

In some embodiments, the fuse router 330 may control electrical connections between the column decoder 150 and the first to third fuse sets (322 to 326) so that the fuse block 300 corresponds to a normal memory cell block determined by a fuse mode control signal (FCM) included in the fuse control signal (FC).

In some embodiments, the fuse router 330 may control electrical connections between the column decoder 150 and the first to third fuse sets (322 to 326) according to a redundancy switching control signal (FCS) included in the fuse control signal (FC), so that the repair address output from the column decoder 150 can be changed.

In FIG. 3, an embodiment has been described in which the fuse block 300 includes three fuse power circuits (312 to 316) and three fuse sets (322 to 326), but the scope of the present disclosure is not limited thereto. That is, the fuse power circuits and the fuse sets may be implemented in a plurality of numbers other than three.

FIG. 5 is a schematic diagram illustrating an example operation of the fuse power controller 310 of the fuse block 300 shown in FIG. 3 according to an embodiment of the present disclosure.

Referring to FIG. 5, a fuse block 500 may include a fuse power controller 510 and a fuse circuit 520, which are examples of the fuse power controller 310 and the fuse circuit 320 included in the fuse block 300 shown in FIG. 3. For convenience of description, some components (e.g., the fuse router 330) of the fuse block 500 are omitted in FIG. 5, but the fuse block 500 may have a structure and function corresponding to those of the fuse block 300. Here, the structure and function of the fuse circuit 520 are substantially the same as those of the fuse circuit 320 described in FIG. 3, and as such redundant descriptions thereof will herein be omitted for brevity.

The fuse power controller 510 may include first to third power transistors (PX1 to PX3) respectively connected to the first to third fuse sets (522 to 526). The first to third power transistors (PX1 to PX3) may correspond to the first to third fuse power circuits (312 to 316) shown in FIG. 3, respectively.

In some embodiments, each of the first to third power transistors (PX1 to PX3) may be implemented as a PMOS transistor.

The first power transistor (PX1) may be connected between a power-supply voltage (VDD) and the first fuse set 522, and a first fuse power control signal (FCP_1) may be received (for example, activated) through a gate terminal of the first power transistor (PX1). When the first fuse power control signal (FCP_1) is at a logic low level, the first power transistor (PX1) may be turned on, so that the power-supply voltage (VDD) can be supplied to the first fuse set 522. When the first fuse power control signal (FCP_1) is at a logic high level, the first power transistor (PX1) may be turned off, thereby preventing the power-supply voltage (VDD) from being supplied to the first fuse set 522. In other words, since the first power transistor (PX1) is opened or closed according to the first fuse power control signal (FCP_1), the first power transistor (PX1) may control the power supply to the first fuse set 522.

Although each of the second and third power transistors (PX2, PX3) receives a fuse power control signal (FCP_2, FCP_3) and is connected to a fuse set, which are different from those of the first power transistor (PX1), the second and third power transistors (PX2, PX3) can perform operations corresponding to those of the first power transistor (PX1), and as such redundant descriptions thereof will herein be omitted for brevity.

In some embodiments, each of the first to third fuse power control signals (FCP_1 to FCP_3) may correspond to one bit included in the fuse power control signal (FCP) described in FIG. 3.

The fuse controller 170 of FIG. 1 may supply or cut off power to each of the first to third fuse sets (522 to 526) by using the first to third fuse power control signals (FCP_1 to FCP_3).

When at least some of the first to third fuse sets (522 to 526) become unnecessary, the fuse controller 170 may cut off power to the corresponding fuse set by setting the fuse power control signal associated with the unnecessary fuse set to a logic high level. For example, when the third fuse set 526 becomes unnecessary, the fuse controller 170 may set each of the first and second fuse power control signals (FCP_1, FCP_2) to a logic low level and set the third fuse power control signal (FCP_3) to a logic high level.

When some fuse sets become unnecessary, for example, when process stabilization of the semiconductor memory device 10 is conducted, this means an example case in which the fuse mode is changed.

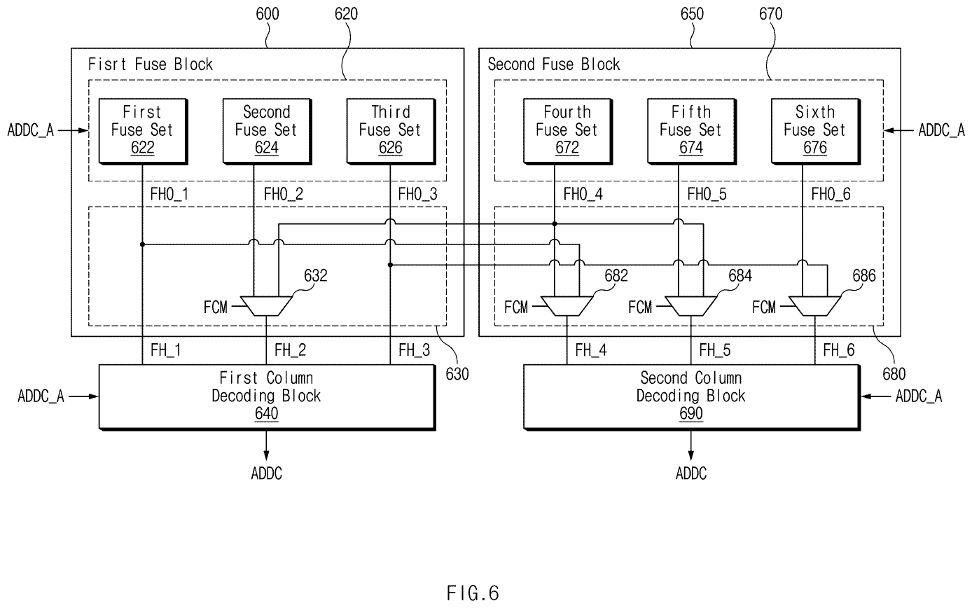

In this instance, process stabilization may refer to a condition in which the probability of defective cell occurrence decreases as the manufacturing process for the semiconductor memory device 10 is improved. The fuse mode represents the correspondence relationship between the fuse circuit 200 and the normal memory cell array 120, and the number (k) of normal memory cell blocks corresponding to one fuse block may be determined depending on the fuse mode. For example, when the fuse mode is changed such that the number of normal memory cell blocks corresponding to one fuse block increases for test time reduction (TTR) (for example, as in the embodiment of FIG. 6 to be described later), some fuse blocks may become unnecessary.

In some embodiments, the fuse controller 170 may determine unnecessary fuse sets based on the types of fuse sets. For example, the fuse controller 170 may sequentially determine some fuse sets among the first to third-type fuse sets (400a to 400c) of FIGS. 4A to 4C to be unnecessary fuse sets. Here, the unnecessary fuse set may be determined in the order of the third-type fuse set 400c, the second-type fuse set 400b, and the first-type fuse set 400a. This is because the NSER characteristics decrease in the order of the third-type fuse set 400c, the second-type fuse set 400b, and the first-type fuse set 400a.

In some embodiments, the first to third fuse power control signals (FCP_1 to FCP_3) may also be supplied to other fuse blocks. In this case, interconnect lines required for transmitting the first to third fuse power control signals (FCP_1 to FCP_3) can be minimized, thereby increasing a layout margin and reducing malfunctions caused by coupling between the interconnect lines.

In another embodiment, the first to third fuse power control signals (FCP_1 to FCP_3) may be supplied differently for each fuse block. In this case, as the fuse power controller is controlled independently for each fuse block, power consumption of the fuse circuit 200 can be minimized.

FIG. 6 is a schematic diagram illustrating an example operation of the fuse router of the fuse block 300 shown in FIG. 3 according to an embodiment of the present disclosure.

Referring to FIG. 6, a first fuse block 600 may include a first fuse circuit 620 and a first fuse router 630, which are examples (for example, respectively) of the fuse circuit 320 and the fuse router 330 included in the fuse block 300 shown in FIG. 3.

A second fuse block 650 may include a second fuse circuit 670 and a second fuse router 680, which are examples (for example, respectively) of the fuse circuit 320 and the fuse router 330 included in the fuse block 300 shown in FIG. 3. For convenience of description, some components (e.g., the fuse power controller 310) of the first fuse block 600 or the second fuse block 650 are omitted from FIG. 6, but the first fuse block 600 and the second fuse block 650 may have structures and functions corresponding to those of the fuse block 300. In this instance, since the structures and functions of the first and second fuse circuits (620, 670) are substantially the same as those of the fuse circuit 320 described in FIG. 3, redundant descriptions thereof will herein be omitted for brevity.

The first fuse router 630 may include a first multiplexer (MUX) 632.

The first multiplexer (MUX) 632 may receive, as input signals, a second original fuse hit signal (FHO_2) from the second fuse set 624 and a fourth original fuse hit signal (FHO_4) from the fourth fuse set 672, and may output either the second original fuse hit signal (FHO_2) of the second fuse set 624 or the fourth original fuse hit signal (FHO_4) of the fourth fuse set 672 according to the fuse mode control signal (FCM).

When the fuse mode control signal (FCM) is at a logic low level, the first multiplexer (MUX) 632 may output the second original fuse hit signal (FHO_2) from the second fuse set 624. Conversely, when the fuse mode control signal (FCM) is at a logic high level, the first multiplexer (MUX) 632 may output the fourth original fuse hit signal (FHO_4) from the fourth fuse set 672.

The second fuse router 680 may include second to fourth multiplexers (MUXs) 682 to 686.

The second multiplexer (MUX) 682 may receive, as input signals, a fourth original fuse hit signal (FHO_4) from the fourth fuse set 672 and a first original fuse hit signal (FHO_1) from the first fuse set 622, and may output either the fourth original fuse hit signal (FHO_4) from the fourth fuse set 672 or the first original fuse hit signal (FHO_1) from the first fuse set 622 according to the fuse mode control signal (FCM).

When the fuse mode control signal (FCM) is at a logic low level, the second multiplexer (MUX) 682 may output the fourth original fuse hit signal (FHO_4) from the fourth fuse set 672. Conversely, when the fuse mode control signal (FCM) is at a logic high level, the second multiplexer (MUX) 682 may output the first original fuse hit signal (FHO_1) from the first fuse set 622.

The third multiplexer (MUX) 684 may receive, as input signals, a fifth original fuse hit signal (FHO_5) from the fifth fuse set 674 and a fourth original fuse hit signal (FHO_4) from the fourth fuse set 672, and may output either the fifth original fuse hit signal (FHO_5) from the fifth fuse set 674 or the fourth original fuse hit signal (FHO_4) from the fourth fuse set 672 according to the fuse mode control signal (FCM).

When the fuse mode control signal (FCM) is at a logic low level, the third multiplexer (MUX) 684 may output the fifth original fuse hit signal (FHO_5) from the fifth fuse set 674. Conversely, when the fuse mode control signal (FCM) is at a logic high level, the third multiplexer (MUX) 684 may output the fourth original fuse hit signal (FHO_4) from the fourth fuse set 672.

The fourth multiplexer (MUX) 686 may receive, as input signals, a sixth original fuse hit signal (FHO_6) from the sixth fuse set 676 and a third original fuse hit signal (FHO_3) from the third fuse set 626, and may output either the sixth original fuse hit signal (FHO_6) from the sixth fuse set 676 or the third original fuse hit signal (FHO_3) from the third fuse set 626 according to the fuse mode control signal (FCM).

When the fuse mode control signal (FCM) is at a logic low level, the fourth multiplexer (MUX) 686 may output the sixth original fuse hit signal (FHO_6) from the sixth fuse set 676. Conversely, when the fuse mode control signal (FCM) is at a logic high level, the fourth multiplexer (MUX) 686 may output the third original fuse hit signal (FHO_3) from the third fuse set 626.

In the example of FIG. 6, it is assumed that the fuse mode includes a first mode and a second mode. The first mode may be a mode in which the number of normal memory cell blocks corresponding to one fuse block is P (where P is an integer equal to or greater than 1, for example, 4). The second mode may be a mode in which the number of normal memory cell blocks corresponding to one fuse block is 2P. That is, in the second mode, the number of normal memory cell blocks corresponding to one fuse block may be doubled compared to that in the first mode. In this instance, the correspondence between a fuse block and a normal memory cell block may indicate that the fuse block stores fail addresses of defective cells included in the corresponding normal memory cell block.

In the first mode, the first fuse circuit 620 of the first fuse block 600 may correspond to a normal memory cell block associated with the first column decoding block 640, and the second fuse circuit 670 of the second fuse block 650 may correspond to a normal memory cell block associated with the second column decoding block 690. That is, the first fuse circuit 620 of the first fuse block 600 may store fail addresses of defective cells included in the normal memory cell block corresponding to the first column decoding block 640, and the second fuse circuit 670 of the second fuse block 650 may store fail addresses of defective cells included in the normal memory cell block corresponding to the second column decoding block 690.

In the second mode, the first fuse circuit 620 of the first fuse block 600 may correspond to both the normal memory cell block associated with the first column decoding block 640 and the normal memory cell block associated with the second column decoding block 690. That is, the first fuse circuit 620 of the first fuse block 600 may store fail addresses of defective cells included in both the normal memory cell block corresponding to the first column decoding block 640 and the normal memory cell block corresponding to the second column decoding block 690. Accordingly, the second fuse circuit 670 of the second fuse block 650 need not operate in the second mode as the first fuse circuit 620 of the first fuse block 600 stores fail addresses of defective cells included in both of the normal memory cell blocks corresponding to the first column decoding block 640 and the second column decoding block 690, and the fuse controller 170 may cut off power to be supplied to the second fuse circuit 670 by using a fuse power control signal transmitted to the second fuse block 650.

However, as will be described later, when the fourth fuse set 672 is to be used instead of the second fuse set 624 in the second mode, the fuse controller 170 may cut off the power to be supplied to the second fuse set 624 rather than to the fourth fuse set 672.

When the fuse mode is the first mode, the fuse controller 170 may generate a fuse mode control signal (FCM) having a logic low level, and may supply the fuse mode control signal (FCM) to the fuse circuit 200.

As the fuse mode control signal (FCM) is at a logic low level, the first fuse router 630 may output the first original fuse hit signal (FHO_1) as the first fuse hit signal (FH_1), may output the second original fuse hit signal (FHO_2) as the second fuse hit signal (FH_2), and may output the third original fuse hit signal (FHO_3) as the third fuse hit signal (FH_3). Accordingly, when one of the first to third original fuse hit signals (FHO_1 to FHO_3) is at a logic high level, the first column decoding block 640 may convert the access column address (ADDC_A) based on the original fuse hit signal having the logic high level, and may output the converted column address (ADDC). When all of the first to third original fuse hit signals (FHO_1 to FHO_3) have a logic low level, the first column decoding block 640 may bypass the access column address (ADDC_A), and may output the column address (ADDC).

As the fuse mode control signal (FCM) is at a logic low level, the second fuse router 680 may output the fourth original fuse hit signal (FHO_4) as the fourth fuse hit signal (FH_4), may output the fifth original fuse hit signal (FHO_5) as the fifth fuse hit signal (FH_5), and may output the sixth original fuse hit signal (FHO_6) as the sixth fuse hit signal (FH_6). Accordingly, when one of the fourth to sixth original fuse hit signals (FHO_4 to FHO_6) is at a logic high level, the second column decoding block 690 may convert the access column address (ADDC_A) based on the original fuse hit signal having the logic high level, and may output the column address (ADDC). When all of the fourth to sixth original fuse hit signals (FHO_4 to FHO_6) have a logic low level, the second column decoding block 690 may bypass the access column address (ADDC_A), and may output the column address (ADDC).

When the fuse mode is the second mode, the fuse controller 170 may generate a fuse mode control signal (FCM) having a logic high level, and may supply the fuse mode control signal (FCM) to the fuse circuit 200.

As the fuse mode control signal (FCM) is at a logic high level, the first fuse router 630 may output the first original fuse hit signal (FHO_1) as the first fuse hit signal (FH_1), may output the fourth original fuse hit signal (FHO_4) as the second fuse hit signal (FH_2), and may output the third original fuse hit signal (FHO_3) as the third fuse hit signal (FH_3). Accordingly, when one of the first, third, and fourth original fuse hit signals (FHO_1, FHO_3, FHO_4) has a logic high level, the first column decoding block 640 may convert the access column address (ADDC_A) based on the original fuse hit signal having the logic high level, and may output the column address (ADDC). When all of the first, third, and fourth original fuse hit signals (FHO_1, FHO_3, FHO_4) have a logic low level, the first column decoding block 640 may bypass the access column address (ADDC_A), and may output the column address (ADDC).

As the fuse mode control signal (FCM) is at a logic low level, the second fuse router 680 may output the first original fuse hit signal (FHO_1) as the fourth fuse hit signal (FH_4), may output the fourth original fuse hit signal (FHO_4) as the fifth fuse hit signal (FH_5), and may output the third original fuse hit signal (FHO_3) as the sixth fuse hit signal (FH_6). Accordingly, when one of the first, third, and fourth original fuse hit signals (FHO_1, FHO_3, FHO_4) has a logic high level, the second column decoding block 690 may convert the access column address (ADDC_A) based on the original fuse hit signal having the logic high level, and may output the column address (ADDC). When all of the first, third, and fourth original fuse hit signals (FHO_1, FHO_3, FHO_4) have a logic low level, the second column decoding block 690 may bypass the access column address (ADDC_A), and may the column address (ADDC).

That is, in the second mode, only three fuse sets (622, 626, 672) among the six fuse sets (622 to 626 and 672 to 676) included in the first fuse block 600 and the second fuse block 650 may be used, while the remaining three fuse sets (624, 674, 676) other than the three fuse sets (622, 626, 672) may not be used.

Moreover, as previously assumed, since each of the first fuse set 622 and the fourth fuse set 672 has the structure of the first-type fuse set 400a, and each of the second, third, fifth, and sixth fuse sets (624, 626, 674, 676) has the structure of the third-type fuse set 400c, the first fuse set 622 and the fourth fuse set 672 may exhibit superior NSER characteristics compared to the second, third, fifth, and sixth fuse sets (624, 626, 674, 676).

In the embodiment of FIG. 6, rather than using all three fuse sets included in either the first fuse block 600 or the second fuse block 650 among the six fuse sets (622 to 626 and 672 to 676) in the second mode, the CCL-based fourth fuse set 672 may be used instead of the SL-based second fuse set 624 in order to maximize NSER characteristics.

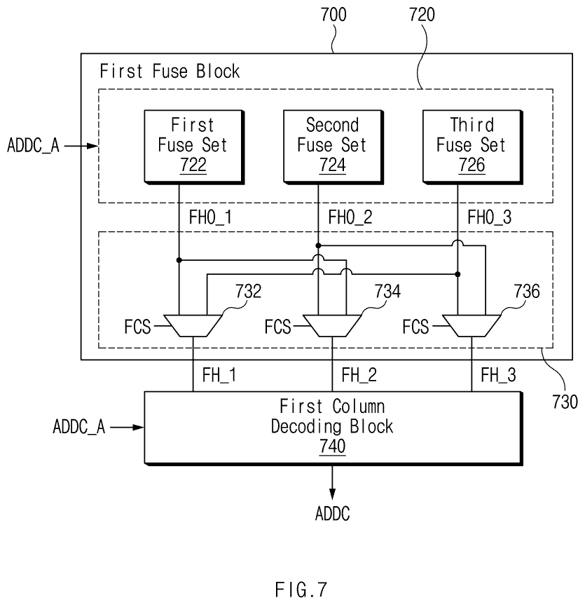

FIG. 7 is a schematic diagram illustrating another example of the operation of the fuse router of the fuse block 300 shown in FIG. 3 according to an embodiment of the present disclosure.

Referring to FIG. 7, a first fuse block 700 may include a first fuse circuit 720 and a first fuse router 730, which are examples of the fuse circuit 320 and the fuse router 330 included in the fuse block 300 shown in FIG. 3.

For convenience of description, some components (e.g., the fuse power controller 310) of the first fuse block 700 are omitted from FIG. 7, but the first fuse block 700 may have a structure and function corresponding to those of the fuse block 300. Here, since the structure and function of the first fuse circuit 720 are substantially the same as those of the fuse circuit 320 described in FIG. 3, redundant descriptions thereof will herein be omitted for brevity.

The first fuse router 730 may include a first multiplexer (MUX) 732, a second multiplexer (MUX) 734, and a third multiplexer (MUX) 736.

The first multiplexer (MUX) 732 may receive, as input signals, a first original fuse hit signal (FHO_1) from the first fuse set 722 and a third original fuse hit signal (FHO_3) from the third fuse set 726, and may output either the first original fuse hit signal (FHO_1) from the first fuse set 722 or the third original fuse hit signal (FHO_3) from the third fuse set 726 according to the redundancy switching control signal (FCS).

When the redundancy switching control signal (FCS) is at a logic low level, the first multiplexer (MUX) 732 may output the first original fuse hit signal (FHO_1) from the first fuse set 722. Conversely, when the redundancy switching control signal (FCS) is at a logic high level, the first multiplexer (MUX) 732 may output the third original fuse hit signal (FHO_3) from the third fuse set 726.

The second multiplexer (MUX) 734 may receive, as input signals, a second original fuse hit signal (FHO_2) from the second fuse set 724 and a first original fuse hit signal (FHO_1) from the first fuse set 722, and may output either the second original fuse hit signal (FHO_2) from the second fuse set 724 or the first original fuse hit signal (FHO_1) from the first fuse set 722 according to the redundancy switching control signal (FCS).

When the redundancy switching control signal (FCS) is at a logic low level, the second multiplexer (MUX) 734 may output the second original fuse hit signal (FHO_2) from the second fuse set 724. Conversely, when the redundancy switching control signal (FCS) is at a logic high level, the second multiplexer (MUX) 734 may output the first original fuse hit signal (FHO_1) from the first fuse set 722.

The third multiplexer (MUX) 736 may receive, as input signals, a third original fuse hit signal (FHO_3) from the third fuse set 726 and a second original fuse hit signal (FHO_2) from the second fuse set 724, and may output either the third original fuse hit signal (FHO_3) from the third fuse set 726 or the second original fuse hit signal (FHO_2) from the second fuse set 724 according to the redundancy switching control signal (FCS).

When the redundancy switching control signal (FCS) is at a logic low level, the third multiplexer (MUX) 736 may output the third original fuse hit signal (FHO_3) from the third fuse set 726. Conversely, when the redundancy switching control signal (FCS) is at a logic high level, the third multiplexer (MUX) 736 may output the second original fuse hit signal (FHO_2) from the second fuse set 724.

A defect may also occur in a redundant memory cell array corresponding to a repair address (or a column address ADDC when a fuse hit signal is at a logic high level) output from the first column decoding block 740. Such defects may be detected through a test operation performed either before or after shipment of the semiconductor memory device 10. The fuse controller 170 may store in advance the repair address corresponding to the defective cell. Thereafter, when the fuse controller 170 determines that the access column address (ADDC_A) corresponds to the repair address for the defective cell, the fuse controller 170 may generate a redundancy switching control signal (FCS) having a logic high level. Conversely, when the fuse controller 170 determines that the access column address (ADDC_A) does not correspond to the repair address of the defective cell, the fuse controller 170 may generate a redundancy switching control signal (FCS) having a logic low level. Through this operation of the fuse controller 170, the first column decoding block 740 may not output the repair address corresponding to the defective cell.

As the redundancy switching control signal (FCS) is at a logic low level, the first fuse router 730 may output the first original fuse hit signal (FHO_1) as the first fuse hit signal (FH_1), may output the second original fuse hit signal (FHO_2) as the second fuse hit signal (FH_2), and may output the third original fuse hit signal (FHO_3) as the third fuse hit signal (FH_3). Accordingly, when one of the first to third original fuse hit signals (FHO_1 to FHO_3) is at a logic high level, the first column decoding block 740 may convert the access column address (ADDC_A) based on the original fuse hit signal having the logic high level, and may output a column address (ADDC) (i.e., a repair address). When all of the first to third original fuse hit signals (FHO_1 to FHO_3) have a logic low level, the first column decoding block 740 may bypass the access column address (ADDC_A), and may output the column address (ADDC) (e.g., a normal address).

As the redundancy switching control signal (FCS) is at a logic high level, the first fuse router 730 may output the third original fuse hit signal (FHO_3) as the first fuse hit signal (FH_1), may output the first original fuse hit signal (FHO_1) as the second fuse hit signal (FH_2), and may output the second original fuse hit signal (FHO_2) as the third fuse hit signal (FH_3). Accordingly, when one of the first to third original fuse hit signals (FHO_1 to FHO_3) is at a logic high level, the first column decoding block 740 may convert the access column address (ADDC_A) based on the original fuse hit signal having the logic high level, and may output the column address (ADDC) (i.e., a repair address). When all of the first to third original fuse hit signals (FHO_1-FHO_3) have a logic low level, the first column decoding block 740 may bypass the access column address (ADDC_A), and may output the column address (ADDC) (i.e., a normal address).

It is assumed that a specific access column address (ADDC_A) is stored in the first fuse set 722 and that the specific access column address (ADDC_A) corresponds to a repair address associated with a defective cell.

Assuming that the first multiplexer (MUX) 732 and the second multiplexer (MUX) 734 are not included in the first fuse block 700, when the first fuse block 700 receives a specific access column address (ADDC_A), the first fuse hit signal (FH_1) transitions to a logic high level, and the first column decoding block 740 outputs a repair address corresponding to the defective cell (hereinafter referred to as a “defective repair address”) based on the first fuse hit signal (FH_1) having the logic high level. To prevent this phenomenon, when a defective repair address is detected through a test operation, it is necessary to re-store the specific access column address (ADDC_A) in the second or third fuse set (724 or 726) instead of the first fuse set 722.

However, since the second or third fuse set (724 or 726) has lower NSER characteristics than the first fuse set 722, the above-described method may lead to performance degradation of the semiconductor memory device 10.

According to the embodiment of FIG. 7, when a specific access column address (ADDC_A) is input to the first fuse block 700, the first fuse router 730 may output the third original fuse hit signal (FHO_3) as the first fuse hit signal (FH_1) instead of the first original fuse hit signal (FHO_1). As a result, the column decoding block 740 may output a normal address corresponding to the third fuse set 726 instead of outputting the defective repair address corresponding to the first fuse set 722.

In addition, even when a specific access column address (ADDC_A) is stored in the second fuse set 724 or the third fuse set 726 and corresponds to a repair address associated with a defective cell, the first column decoding block 740 may output a normal address corresponding to the first fuse set 722 or the second fuse set 724, instead of outputting the defective repair address corresponding to the second fuse set 724 or the third fuse set 726.

In FIGS. 6 and 7, the fuse routers (630, 680, 730) are illustrated as including multiplexers (MUXs) to control electrical connections, but the scope of the present disclosure is not limited thereto, and the fuse routers (630, 680, 730) may include, for example, transistors that perform switching functions.

The embodiments described in FIGS. 5 to 7 are not mutually exclusive and may be implemented in combination with one another. In other words, two or more of the embodiments described in FIGS. 5 to 7 may be combined and implemented as needed.

For example, each fuse set (622, 624, 626) of the first fuse circuit 620 shown in FIG. 6 may be connected to each power transistor (PX1-PX3) of the fuse power controller 510 shown in FIG. 5.

In another example, the first fuse router 730 of FIG. 7 may be connected below the first fuse router 630 of FIG. 6. Accordingly, the first to third fuse hit signals (FH_1 to FH_3) output from the first fuse router 630 may be input to the first to third multiplexers (732-736) of the first fuse router 730, respectively.

The present disclosure provides a semiconductor memory device 10 that includes a fuse circuit 200 having optimal reliability and optimal area efficiency. In addition, as different types of fuse sets included in the fuse circuit 200 are controlled according to various conditions, power consumption can be reduced and reliability characteristics can be improved.

As is apparent from the above description, the embodiments of the present disclosure may provide the semiconductor memory device including a fuse circuit having optimal reliability and optimal area efficiency.

In addition, the semiconductor memory device may control different types of fuse sets included in the fuse circuit according to various conditions, so that power consumption can be reduced and reliability characteristics can be improved.

The embodiments of the present disclosure may provide a variety of effects capable of being directly or indirectly recognized through the above-mentioned patent document.

Those skilled in the art will appreciate that the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in this patent document.

What is claimed is:

1. A fuse circuit of a semiconductor memory device comprising:
a plurality of fuse blocks, each of the plurality of fuse blocks including a first fuse set and a second fuse set, and configured to output, in response to an access column address, a fuse hit signal indicating whether the access column address is programmed,
wherein
the second fuse set is of a different type from the first fuse set.

2. The fuse circuit of the semiconductor memory device according to claim 1, wherein each of the first fuse set and the second fuse set includes:
an enable fuse latch configured to program data indicating whether a corresponding fuse set is being used for the access column address; and
an address fuse latch configured to program a fail address of a defective cell included in a normal memory cell block associated with the corresponding fuse set.

3. The fuse circuit of the semiconductor memory device according to claim 2, wherein:
each of the enable fuse latch and the address fuse latch of the first fuse set includes a cross-coupled latch (CCL)-based fuse latch; and
the address fuse latch of the second fuse set includes a single latch (SL)-based fuse latch.

4. The fuse circuit of the semiconductor memory device according to claim 1, wherein each of the plurality of fuse blocks further includes:
a first fuse power circuit configured to control power to be supplied to the first fuse set in response to a first fuse power control signal; and
a second fuse power circuit configured to control power to be supplied to the second fuse set in response to a second fuse power control signal.

5. The fuse circuit of the semiconductor memory device according to claim 4, wherein:
the first fuse power control signal and the second fuse power control signal have different logic levels from each other.

6. The fuse circuit of the semiconductor memory device according to claim 5, wherein:
each of the first fuse power circuit and the second fuse power circuit includes a PMOS transistor that receives a power-supply voltage.

7. The fuse circuit of the semiconductor memory device according to claim 6, wherein:
the first fuse power control signal has a logic low level; and
the second fuse power control signal has a logic high level.

8. The fuse circuit of the semiconductor memory device according to claim 1, wherein:
the first fuse set is configured to output a first original fuse hit signal indicating whether the access column address is programmed in the first fuse set; and
the second fuse set is configured to output a second original fuse hit signal indicating whether the access column address is programmed in the second fuse set.

9. The fuse circuit of the semiconductor memory device according to claim 8, wherein each of the plurality of fuse blocks further includes:
a fuse router configured to route the first original fuse hit signal and the second original fuse hit signal, and to output a first fuse hit signal and a second fuse hit signal included in the fuse hit signal.

10. The fuse circuit of the semiconductor memory device according to claim 9, wherein:
the plurality of fuse blocks includes a first fuse block and a second fuse block that operate in a first mode or a second mode,
wherein the number of normal memory cell blocks corresponding to the first fuse block in the first mode is less than the number of normal memory cell blocks corresponding to the first fuse block in the second mode.

11. The fuse circuit of the semiconductor memory device according to claim 10, wherein:
in the first mode, the fuse router of the first fuse block outputs the first original fuse hit signal of the first fuse set included in the first fuse block as the first fuse hit signal, and outputs the second original fuse hit signal of the second fuse set included in the first fuse block as the second fuse hit signal; and
in the first mode, the fuse router of the second fuse block outputs a first original fuse hit signal of the first fuse set included in the second fuse block as the first fuse hit signal, and outputs the second original fuse hit signal of the second fuse set included in the second fuse block as the second fuse hit signal.

12. The fuse circuit of the semiconductor memory device according to claim 10, wherein:
in the second mode, each of the fuse router of the first fuse block and the fuse router of the second fuse block outputs the first original fuse hit signal of the first fuse set included in the first fuse block as the first fuse hit signal, and outputs the first original fuse hit signal of the first fuse set included in the second fuse block as the second fuse hit signal.

13. The fuse circuit of the semiconductor memory device according to claim 10, wherein the fuse router of the first fuse block includes:
a first multiplexer (MUX) configured to output, in response to a fuse mode control signal indicating the first mode or the second mode, one of the second original fuse hit signal of the second fuse set included in the first fuse block and the first original fuse hit signal of the first fuse set included in the second fuse block.

14. The fuse circuit of the semiconductor memory device according to claim 10, wherein the fuse router of the second fuse block includes:
a second multiplexer (MUX) configured to output, in response to a fuse mode control signal indicating the first mode or the second mode, one of the first original fuse hit signal of the first fuse set included in the second fuse block and the first original fuse hit signal of the first fuse set included in the first fuse block; and
a third multiplexer (MUX) configured to output, in response to the fuse mode control signal, one of the second original fuse hit signal of the second fuse set included in the second fuse block and the first original fuse hit signal of the first fuse set included in the second fuse block.

15. The fuse circuit of the semiconductor memory device according to claim 9, wherein:
in response to a redundancy switching control signal, the fuse router outputs the first original fuse hit signal of the first fuse set as the second fuse hit signal, and outputs the second original fuse hit signal of the second fuse set as the first fuse hit signal.

16. A fuse circuit of a semiconductor memory device comprising:
a first fuse set configured to output a first original fuse hit signal indicating whether an access column address is programmed;
a second fuse set configured to output a second original fuse hit signal indicating whether the access column address is programmed, the second fuse set being of a different type from the first fuse set; and
a fuse router configured to route the first original fuse hit signal and the second original fuse hit signal and to output a first fuse hit signal and a second fuse hit signal.

17. The fuse circuit of the semiconductor memory device according to claim 16, wherein the fuse router includes:
a multiplexer (MUX) configured to receive the first original fuse hit signal or the second original fuse hit signal and to select one of the first original fuse hit signal or the second original fuse hit signal as an output signal in response to a fuse control signal.

18. A semiconductor memory device comprising:
a fuse circuit configured to output a fuse hit signal indicating whether an access column address is programmed, in response to the access column address; and
a column decoder configured to generate a column address by converting the access column address based on the fuse hit signal,
wherein the fuse circuit includes a first fuse set and a second fuse set which is of a different type from the first fuse set.

19. The semiconductor memory device according to claim 18, wherein each of the first fuse set and the second fuse set includes:
an enable fuse latch configured to program data indicating whether a corresponding fuse set is being used for the access column address; and
an address fuse latch configured to program a fail address of a defective cell included in a normal memory cell block associated with the corresponding fuse set.

20. The semiconductor memory device according to claim 19, wherein:
each of the enable fuse latch and the address fuse latch of the first fuse set includes a cross-coupled latch (CCL)-based fuse latch; and
the address fuse latch of the second fuse set includes a single latch (SL)-based fuse latch.
